(19) United States
(12) Patent Application Publication
(10) Pub. No.: US 2023/0411265 A1
(43) Pub. Date: Dec. 21, 2023

(54) SPLIT SEMICONDUCTOR PACKAGE

(71) Applicant: Texas Instruments Incorporated, Dallas, TX (US)

(72) Inventors: John Carlo Molina, Bataan (PH); Ray Fredric De Asis, MABALACAT CITY (PH); Tracee Kay De Asis, MABALACAT CITY (PH)

(21) Appl. No.: 17/844,920

(22) Filed: Jun. 21, 2022

(51) Int. Cl. H01L 23/498; H01L 23/00

(52) U.S. Cl. CPC H01L 23/49838; H01L 23/49861; H01L 2224/48245; H01L 24/97; H01L 24/48; H01L 24/96

(57) ABSTRACT

An electronic device includes a package structure, a semiconductor die and a set of conductive leads, in which the package structure has a triangular shape with a bottom first side, a top second side and lateral third, fourth, and fifth sides. The set of conductive leads extend along the third side with one of the set of conductive leads electrically coupled to a conductive terminal of the semiconductor die, the package structure encloses a portion of the semiconductor die and portions of the set of conductive leads, and the package structure exposes further portions of the set of conductive leads along the first side and additional portions of the set of conductive leads along the third side.

### BACKGROUND

Small outline no-lead (SON) electronic device packages provide a small form factor with low pin count and fine pitch lead spacing for advanced end equipment applications including automotive systems. Quad lead versions, referred to as quad flat no-lead (QFN) packages have leads along four lateral sides, and other small outline no-lead devices have leads on less than all of the sides. As applications continue to call for higher circuit density and smaller packages for mounting on a host printed circuit board (PCB), it is desirable to reduce the size of packaged electronic devices. At the same time, it is desirable to reduce the manufacturing cost for producing integrated circuits and other packaged electronic devices.

### SUMMARY

In one aspect, an electronic device includes a package structure, a semiconductor die and a set of conductive leads. The package structure has a first side, a second side, a third side, a fourth side, and a fifth side, the first side extends in a first plane of orthogonal first and second directions, the second side extends in a second plane of the first and second directions, and the second side is spaced apart from the first side along a third direction that is orthogonal to the first and second directions. The third side extends along the third direction from the first side to the second side and the third side extends along the second direction from the fourth side to the fifth side. The fourth side extends along the third direction from the first side to the second side and the fourth side extends along the first direction from the first side to the fifth side. The fifth side extends from the third side to the fourth side. One of the set of conductive leads is electrically coupled to a conductive terminal of the semiconductor die, the package structure encloses a portion of the semiconductor die and portions of the set of conductive leads, and the package structure exposes further portions of the set of conductive leads along the first side and exposes additional portions of the set of conductive leads along the third side.

In another aspect, a lead frame panel includes an array of rectangular unit regions arranged in rows along a first direction and columns along an orthogonal second direction, with adjacent unit regions joined by metal bars that extend along the respective first and second directions on four sides of the respective rectangular unit regions. The respective unit regions include first and second metal die attach pads, four sets of conductive leads, and a tie bar. A first set of conductive leads is connected to a first one of the metal bars along a first side of the rectangular unit region, a second set of conductive leads connected to a second one of the metal bars along a second side of the rectangular unit region, a third set of conductive leads connected to a third one of the metal bars along a third side of the rectangular unit region, and a fourth set of conductive leads connected to a fourth one of the metal bars along a fourth side of the rectangular unit region. The tie bar is connected to and extends between the first and second metal die attach pads, and the tie bar intersects a prospective cut line that bisects the respective unit region and that intersects opposite corners of the respective unit region.

In a further aspect, a method of fabricating an electronic device includes attaching first and second semiconductor dies to respective first and second die attach pads in each of an array of rectangular unit regions arranged in rows along a first direction and columns along an orthogonal second direction of a lead frame. For each respective unit region, the method includes electrically coupling a conductive terminal of the first semiconductor die to one of a first set of conductive leads of the respective unit region, and electrically coupling a conductive terminal of the second semiconductor die to one of a second set of conductive leads of the respective unit region. The method includes performing a molding process that forms a package structure that encloses the first and second semiconductor dies and portions of the first and second sets of conductive leads. The method further includes performing a first cutting process that cuts through the package structure and metal bars of the lead frame along first cut lines that are parallel to the first direction, performing a second cutting process that cuts through the package structure and further metal bars of the lead frame along second cut lines that are parallel to the second direction, and performing a third cutting process that cuts through the package structure and tie bars along third cut lines that intersect opposite corners of the respective unit regions and bisect the respective unit regions between the first and second metal die attach pads.

### BRIEF DESCRIPTION OF THE DRAWINGS

FIG. 1 is a top perspective view of a five-sided electronic device with a triangular shape.

FIG. 1A is a top plan view of the electronic device.

FIG. 1B is a bottom view of the electronic device.

FIG. 1C is a side elevation view of a fourth side of the electronic device.

FIG. 1D is a side elevation view of a fifth side of the electronic device.

FIG. 1E is a sectional side elevation view of the electronic device taken along line 1E-1E of FIG. 1A.

FIG. 2 is a flow diagram of a method of fabricating an electronic device.

FIGS. 3-9A are partial top plan and sectional side elevation views of the electronic device of FIGS. 1-1E undergoing fabrication processing according to the method of FIG. 2.

FIG. 10 is a partial top perspective view of a system with the electronic device of FIGS. 1-1E soldered to a printed circuit board.

FIG. 10A is a sectional side elevation view the electronic device and printed circuit board taken along line 10A-10A of FIG. 10.

FIG. 11 is a partial top plan view of another electronic device during fabrication prior to package separation.

FIG. 12 is a partial top plan view of yet another electronic device during fabrication prior to package separation.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. Unless otherwise stated, “about,” “approximately,” or “substantially” preceding a value means +/−10 percent of the stated value. One or more operational characteristics of various circuits, systems and/or components are hereinafter described in the context of functions which in some cases result from configuration and/or interconnection of various structures when circuitry is powered and operating.

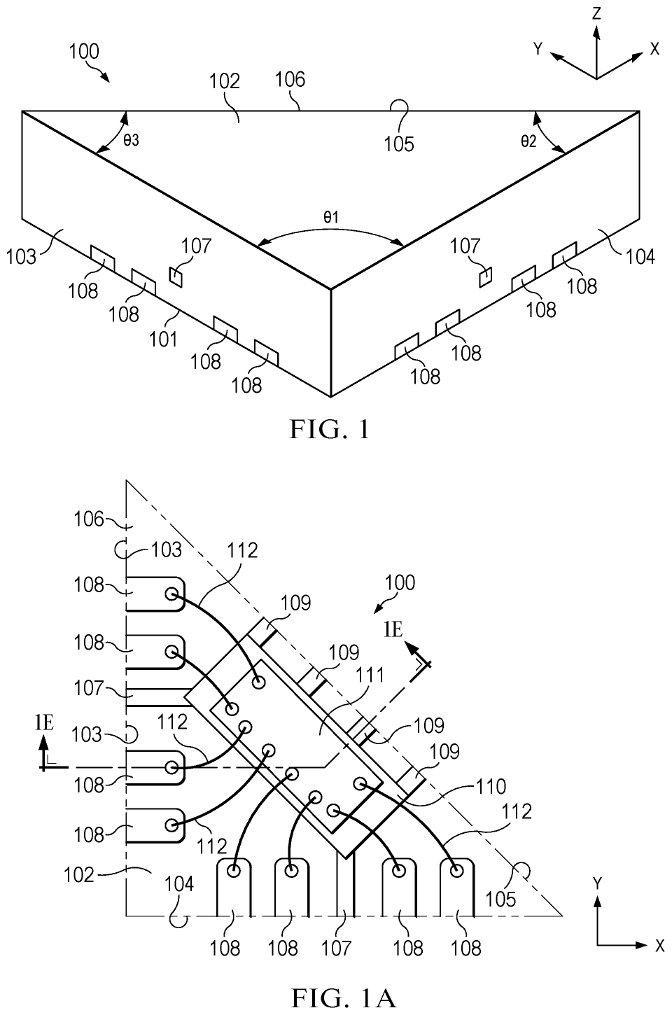

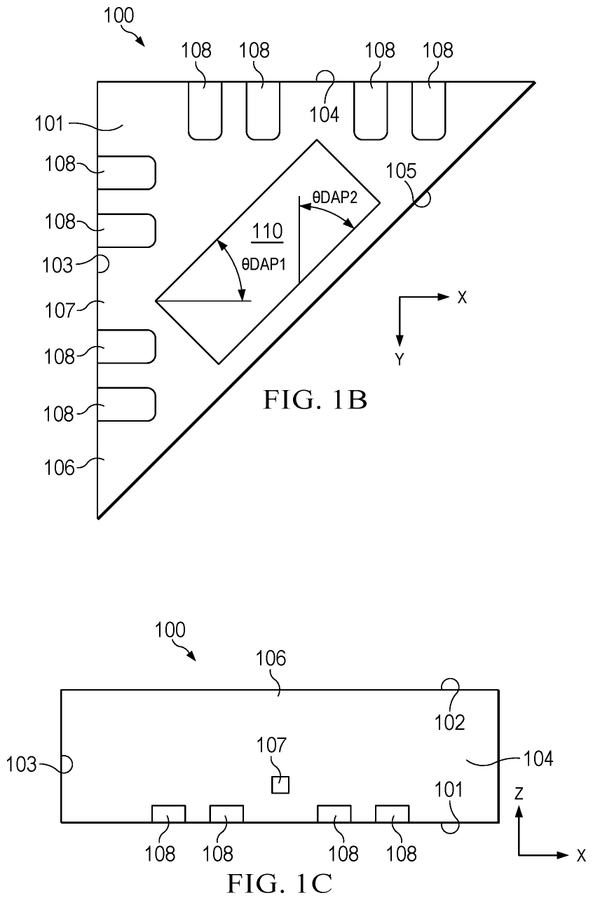

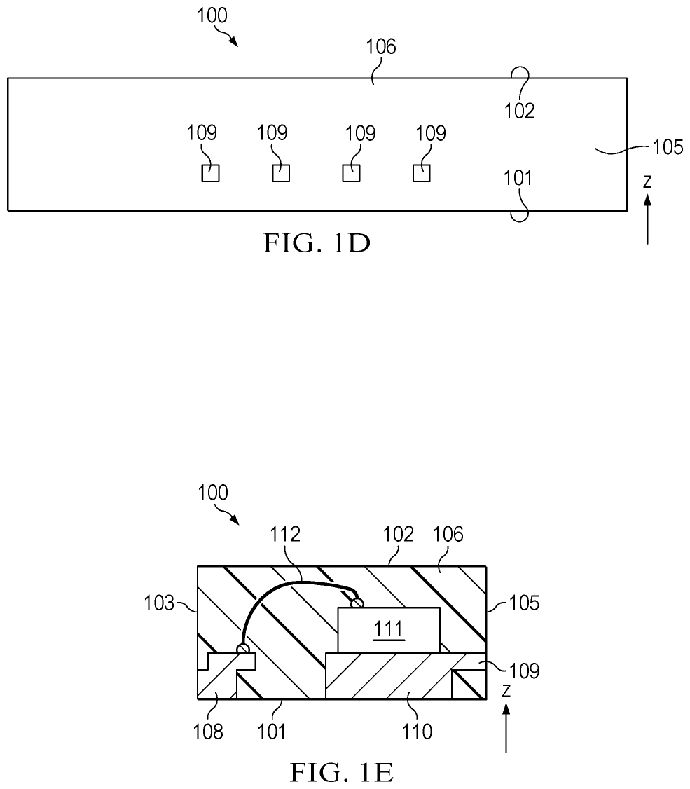

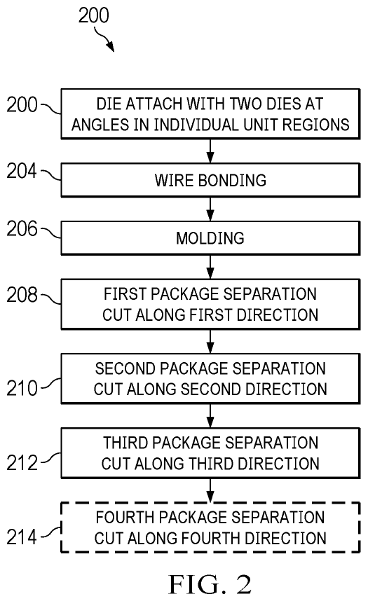

FIGS. 1-1E show a five-sided electronic device 100 with a wedge or triangular shape, including a bottom or first side 101, a top or second side 102, and lateral third, fourth, and fifth sides 103, 104, and 105, respectively. FIG. 1 shows a perspective view of the electronic device 100, FIG. 1A shows a top view, FIG. 1B shows a bottom view, FIG. 1C shows a side view of the fourth side 104, FIG. 1D shows a side view of the fifth side 105, and FIG. 1E shows a section view of the electronic device 100 taken along line 1E-1E in FIG. 1A. The electronic device 100 includes a molded plastic package structure 106 with generally planar sides 101-105. In another implementation, one or more of the sides 101-105 can have non-planar surface features, such as tapered portions resulting from tapered upper and lower mold structures used to form the molded package structure 106 during manufacturing (e.g., slightly angled lower and upper portions of the lateral sides 103 and 104 that joined along a parting line of the mold, not shown). The electronic device 100 includes tie bars 107 exposed along the respective third and fourth sides 103 and 104, leads 108 exposed along the respective first, third, and fourth sides 101, 103 and 104, as well as further tie bars 109 exposed along the fifth side 105.

The electronic device 100 is shown in FIGS. 1-1E in an example three-dimensional space including a first direction X, and an orthogonal second direction Y, and a third direction Z that is orthogonal to the first and second directions X and Y. In the illustrated orientation, the first side 101 (e.g., the bottom side) extends in a first plane of the first and second directions X and Y, the second side 102 (e.g., the top side) extends in a second plane of the first and second directions X and Y, and the second side 102 spaced apart from the first side 101 along the third direction. The third, fourth, and fifth sides 103, 104, and 105 form a triangular shape as shown in FIGS. 1-1B. The third side 103 extends along the third direction Z from the first side 101 to the second side 102 and the third side 103 extends along the second direction Y from the fourth side 104 to the fifth side 105. The fourth side 104 extends along the third direction Z from the first side 101 to the second side 102 and the fourth side 104 extends along the first direction X from the third side 103 to the fifth side 105. In addition, the fifth side 105 extends from the third side 103 to the fourth side 104.

As seen in FIGS. 1A, 1B, and 1D, the electronic device 100 includes a metal die attach pad 110 with an elongated rectangular shape that extends in a plane of the first and second directions X and Y. As shown in FIGS. 1A and 1B, opposite long sides of the die attach pad 110 are parallel to one another and to a plane of the fifth side 105. As best shown in FIG. 1B, the long sides of the die attach pad 110 extend at a first die attach pad angle θDAP1 to the first direction X and at a second die attach pad angle θDAP2 to the second direction Y. In the illustrated example, a lower side of the die attach pad 110 is exposed along the first side 101 of the package structure 106 as seen in FIG. 1B. In one implementation, the bottom or lower side of the die attach pad 110 includes a chamfer or indentation or other physical feature (not shown) to denote the direction and orientation of a first pin (e.g., pin 1) of the finished electronic device 100. In another implementation, the die attach pad 110 is completely enclosed by the package structure 106 and is not exposed along the first side 101.

The tie bars 107 and 109 are connected to the die attach pad 110 and extend in a plane of the first and second directions X and Y. The first tie bars 109 extend from the die attach pad 110 within the package structure 106 and ends of the tie bars 109 are exposed along the fifth side 105 as shown in FIGS. 1A, 1D, and 1E. The second tie bars 107 extend from corners of the die attach pad 110 to the respective third and fourth sides 103 and 104 and are exposed along the respective sides 103 and 104 as shown in FIGS. 1, 1A, and 1C. In the illustrated example, the tie bars 107 and 109 include thin portions created by so-called half-etch processing during fabrication of a starting lead frame, where the thickness of the tie bars 107 and 109 along the third direction Z is less than the thickness of the die attach pad one and 10 and the leads 108, for example, as shown in FIG. 1E. In the illustrated example, moreover, the inner portions of the conductive leads 108 also include half-etch thin features as shown in FIG. 1E. In other implementations, one or more of the half-etch features are omitted, and one or more of the tie bars 107 and 109 and/or the leads 108 are of uniform thickness.

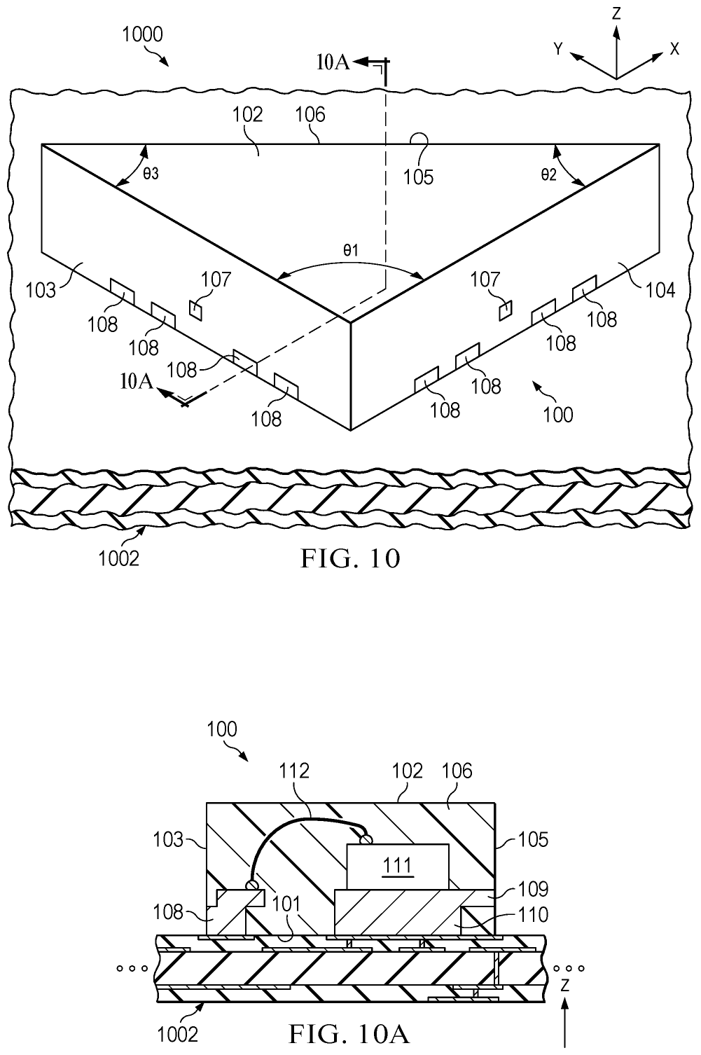

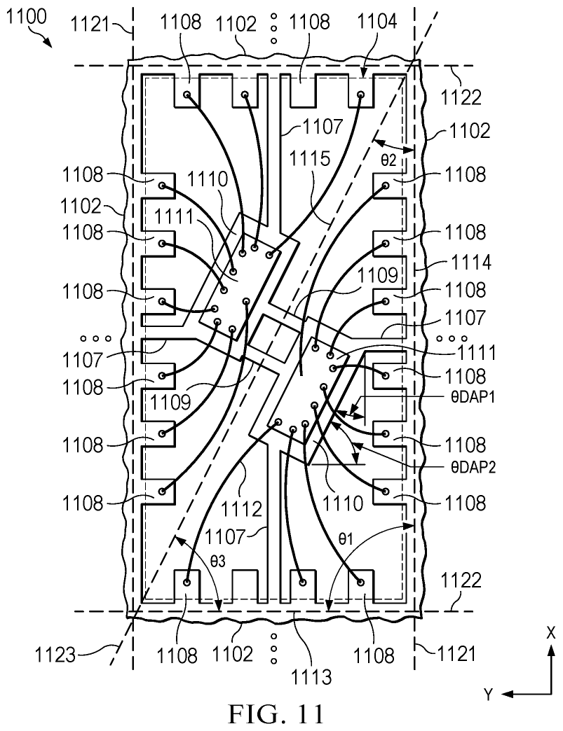

In the example of FIGS. 1-1E, the thicker portions of the leads 108 and the die attach pad 110 extend to the bottom or first side 101 and are exposed along the first side 101 of the package structure 106, for example, to facilitate soldering to a host printed circuit board as illustrated further below in connection with FIGS. 10 and 10A. In the example of FIGS. 1-1E, moreover, the half-etch features of the tie bars 107 and 109 cause the exposed portions thereof to be spaced apart by a non-zero distance from the bottom or first side 101 of the package structure 106 as shown in FIGS. 1, 1C, 1D and 1E. This non-zero spacing mitigates unintended electrical connection to the exposed portions of the tie bars 107 and 109 when the electronic device 100 is soldered to a host printed circuit board. In addition, as discussed further below, the provision of the tie bars 107 and 109 facilitates construction of a starting lead frame in a panel or array during manufacturing of the electronic device 100, for example, to provide support for the die attach pad 110 during die attach processing, wire bonding, molding, etc., and the exposed portions of the tie bars 107 and 109 are cut during separation of finished packaged electronic devices from a starting panel array.

The electronic device 100 includes a semiconductor die 111 mounted on the die attach pad 110. The semiconductor die 111 includes conductive terminals (not numerically designated in the drawings), and the electronic device 100 has bond wires 112 that form electrical connections between conductive terminals of the semiconductor die 111 and respective ones of the conductive leads 108. In other implementations, different electrical interconnection technologies can be used, for example, flip chip soldering, single or multilayer routing structures, etc. (not shown).

The example of FIGS. 1-1D includes a first set of the conductive leads 108 along the third side 103, one or more of which is or are electrically coupled by a corresponding bond wire 112 to a respective conductive terminal of the semiconductor die 111. This example also includes a second set of the conductive leads 108 along the fourth side 104, one or more of which is or are electrically coupled to a respective second conductive terminal of the semiconductor die 111. In other implementations, only one of the third and fourth sides 103 and 104 has conductive leads 108. In the illustrated example, the package structure 106 encloses portions of the first and second sets of conductive leads 108. The package structure 106 exposes further portions of the conductive leads 108 along the first side 101 and additional portions of the conductive leads 108 along the respective third and fourth sides 103 and 104.

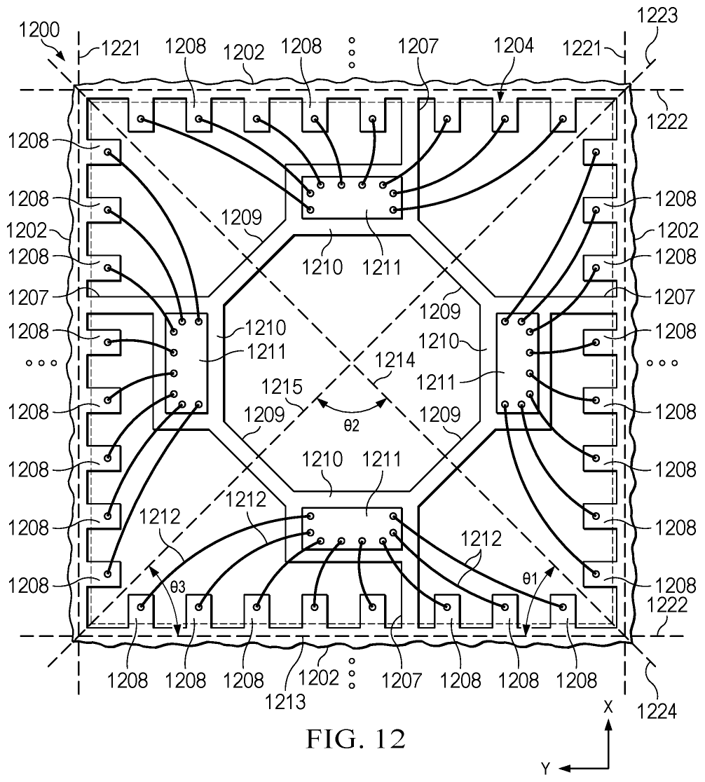

As shown in FIG. 1, a third plane of the third side 103 and a fourth plane of the fourth side 104 are at a first angle θ1, a fifth plane of the fifth side 105 and the fourth plane are at a second angle θ2, and the third and fifth planes are at a third angle θ3. In the example electronic device 100, the first angle θ1 is greater than the second and third angles θ2 and 03. In this example, moreover, the first angle θ1 is approximately 90°, and the second and third angles θ2 and θ3 are equal, such as approximately 45°. Different angles can be used in different implementations. The provision of at least one of the angles at approximately 90° facilitates fabrication processing of multiple electronic devices 100 concurrently in a panel array with rows and columns. In addition, the provision of the other angles (e.g., θ2 and θ3) at approximately 45° also facilitates fabrication processing starting with a lead frame panel or array of generally square unit regions which are then bisected into pairs of triangular-shaped electronic devices as illustrated and described further below. In other examples (e.g., FIG. 11 below), the second and third angles (e.g., θ2 and θ3) can be different, for example, to facilitate fabrication processing using a starting lead frame panel of elongated (e.g., non-unity aspect ratio) rectangular unit regions. And still other examples, a starting rectangular (e.g., square) in a region of a starting lead frame panel array can be separated into more than two packaged electronic devices (e.g., FIG. 12 below).

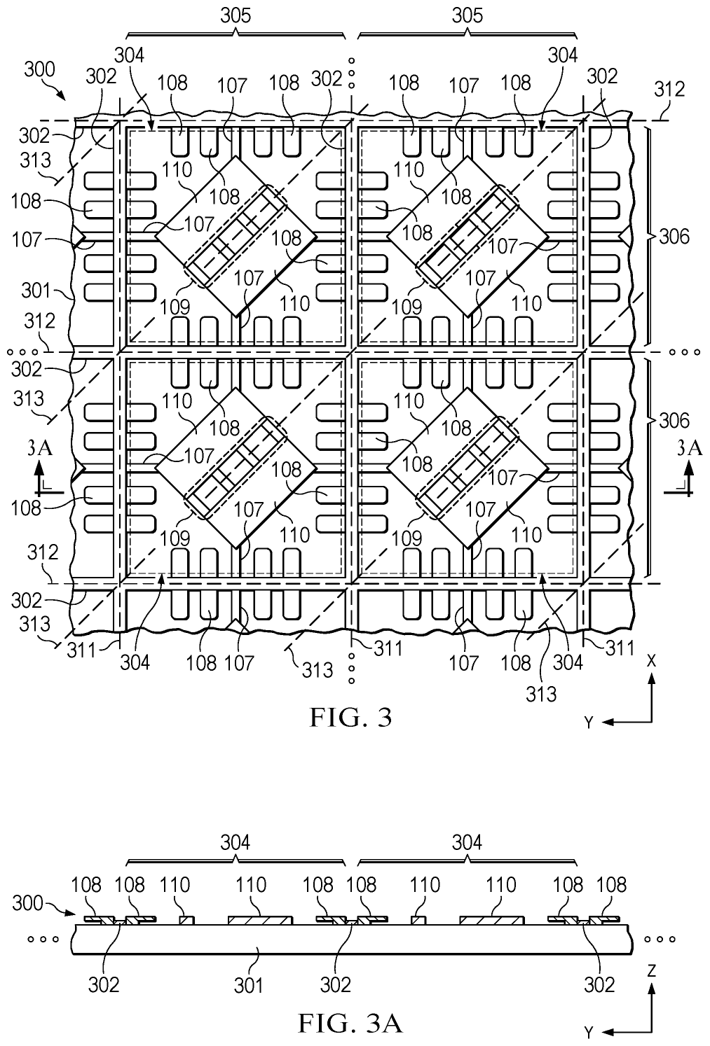

FIG. 2 shows a method 200 of fabricating an electronic device, and FIGS. 3-9A show partial top and sectional side views of the electronic device 100 undergoing fabrication processing according to the method 200. The method 200 includes operations with respect to a starting lead frame panel structure 300 positioned in a plane of the first and second directions X and Y on a carrier structure 301, such as an adhesive tape or other support as shown in FIGS. 3 and 3A. The lead frame panel 300 has metal bars 302 formed along the first direction X and along the second direction Y. The metal bars 302 formed boundaries that define an array of rectangular unit regions 304 arranged in rows 305 along the first direction X and columns 306 along the second direction Y, in which adjacent unit regions 304 are joined by metal bars 302 that extend along the respective first and second directions X, Y on four sides of the respective rectangular unit regions 304. As shown in FIG. 3, the respective unit regions 304 include first and second metal die attach pads 110 in a plane of the first and second directions X and Y, where the long sides of the rectangular die attach pads 110 are angled relative to the first and second directions X and Y as discussed above in connection with FIG. 1B.

The respective square unit regions 304 in this example also have four sets of the conductive leads 108, including a first set of the above described conductive leads 108 connected to a first one of the metal bars 302 along a first side of the rectangular unit region 304, a second set of conductive leads 108 connected to a second one of the metal bars 302 along a second side of the rectangular unit region 304, a third set of conductive leads 108 connected to a third one of the metal bars 302 along a third side of the rectangular unit region 304, and a fourth set of conductive leads 108 connected to a fourth one of the metal bars 302 along a fourth side of the rectangular unit region 304. As further shown in FIG. 3A, one or more of the metal features of the starting lead frame 304 can include half-etch portions, such as the metal bars 302, the tie bars 107 and 109 and/or the conductive leads 108, where the conductive leads in the illustrated example include bottom side half-etch features in the interior portions, as well as top side half-etch features to reduce the lead height at the edges of the finished leads 108 after saw cutting. The starting lead frame 300 in one example is a panel metal structure, such as a metal that is or includes copper, aluminum, or other suitable electrically conductive metal with the features formed by suitable processes such as selective electroplating, chemical etching, stamping, bending, cutting, etc.

In addition, the respective unit regions 304 include the first tie bars 109 that are connected to and extend between the first and second metal die attach pads 110. In addition, the respective unit regions 304 further include a set of the second tie bars 107 that extend from a corner of one of the metal die attach pads 110 to a respective one of the metal bars 302. The metal bars 302 are formed along prospective first cut lines 311 along the first direction X, and prospective second cut lines 312 along the second direction Y, and FIG. 3 further shows prospective third cut lines 313 at 45° to the respective first and second directions X and Y. The tie bars 109 intersect a respective one of the prospective third cut lines 313 that bisects the respective unit region 304 and that intersects opposite corners of the respective unit region 304. The first and second die attach pads 110 have rectangular shapes with opposite sides parallel to the prospective third cut lines 313. The intersection of the prospective cut lines 313 with the corners of the rectangular unit regions 304 facilitates separation cutting operations during fabrication to split the unit regions 304 and form respective pairs of packaged electronic devices having the triangular shapes described above in connection with FIGS. 1-1E.

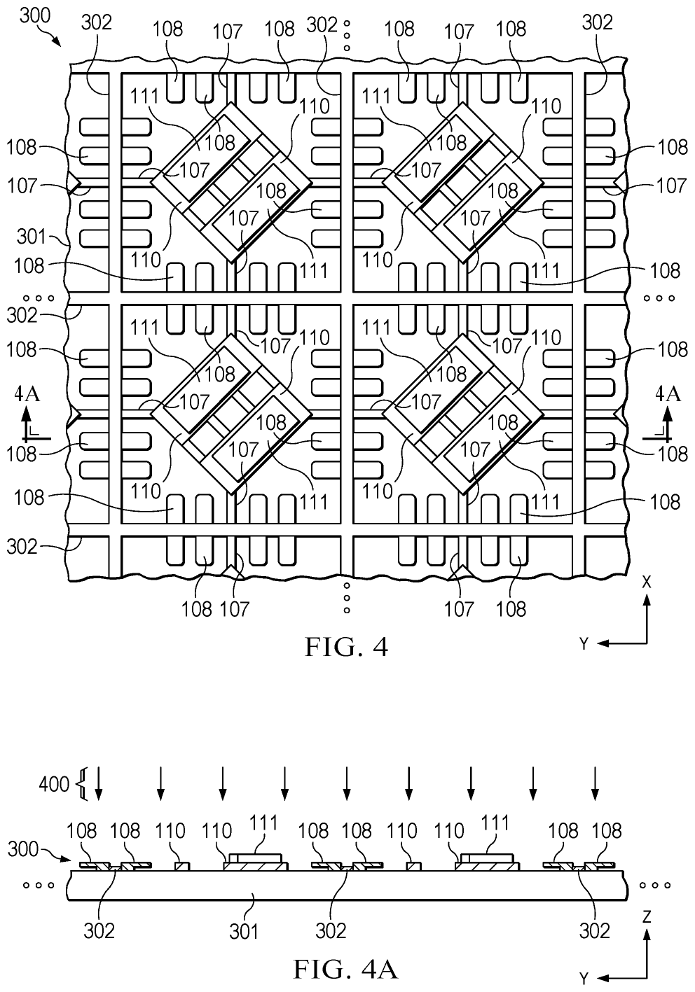

The method 200 in FIG. 2 starts with the lead frame 300 of FIGS. 3 and 3A, and includes die attach processing at 202. FIGS. 4 and 4A show one example, in which a die attach process 400 is performed that attaches first and second semiconductor dies 111 to respective first and second die attach pads 110 in each of an array of the rectangular unit regions 304. In other implementations (e.g., FIG. 12 below), the die attach processing at 202 includes attaching three or more semiconductor dies 111 to respective die attach pads in one or more of the unit regions. In one example, the die attach processing includes forming an adhesive on all or portions of a top side of the respective die attach pads 110 and using an automated pick and place system (not shown), attaching the bottom sides of individual semiconductor dies 111 to respective ones of the die attach pads 110 as shown in FIGS. 4 and 4A. In one example, the die attach processing 400 also includes a thermal curing step to cure the adhesive used in mounting the semiconductor dies 111 to the respective die attach pads 110.

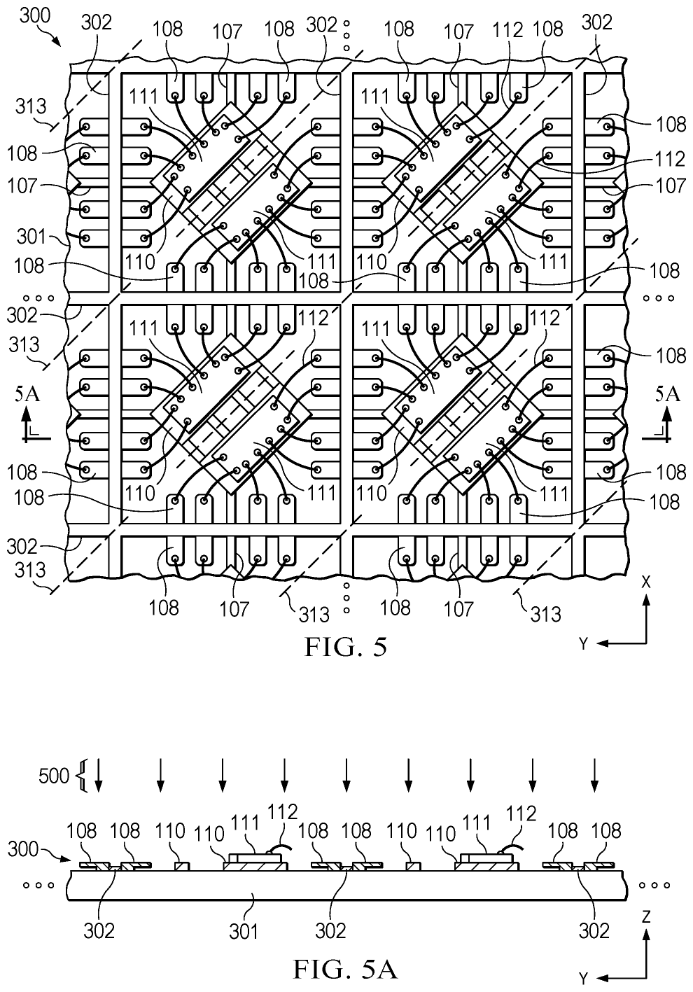

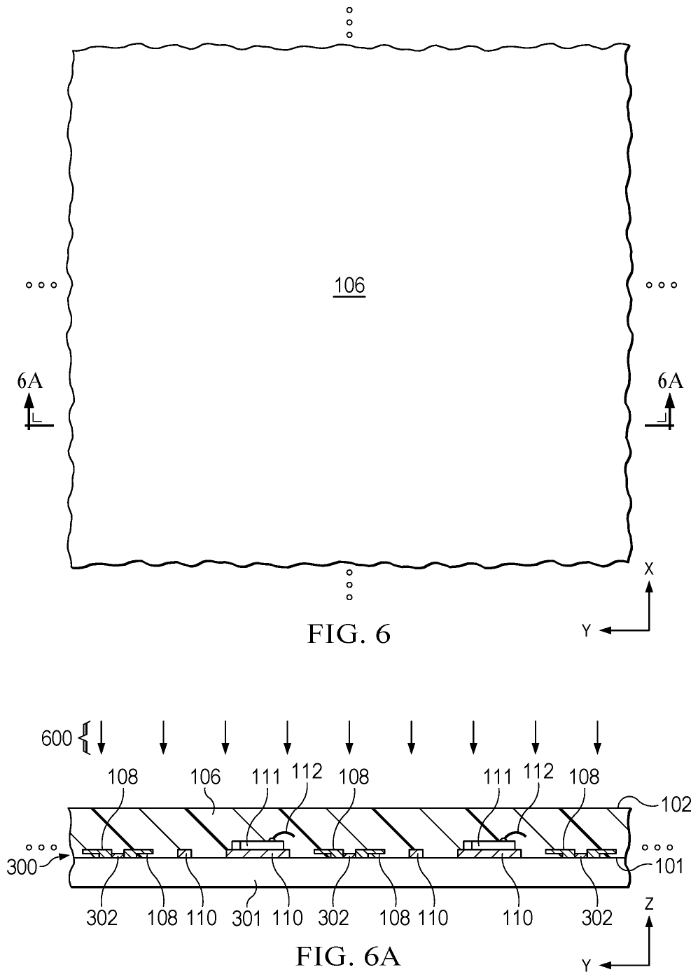

The method 200 continues at 204 with electrical connection processing to electrically couple one or more conductive terminals of the semiconductor dies 111 to respective ones of the conductive leads 108. FIGS. 5 and 5A show one example, in which a wire bonding process 500 is performed that electrically couples one or more conductive terminals of the first semiconductor die 111 to one of a first set of conductive leads 108 of the respective unit region 304, and electrically couples one or more conductive terminals of the second semiconductor die 111 to one of a second set of conductive leads 108 of the respective unit region 304. As shown in FIG. 5, the wire bonding process forms bond wires 112 to make the appropriate electrical connections, where the bond wires 112 do not cross over the prospective third cut lines 313. The method 200 also includes molding at 206. FIGS. 6 and 6A show one example, in which a molding process 600 is performed that forms the package structure 106 that encloses the first and second semiconductor dies 111, the bond wires 112, and portions of the first and second sets of conductive leads 108 in the respective unit regions 304.

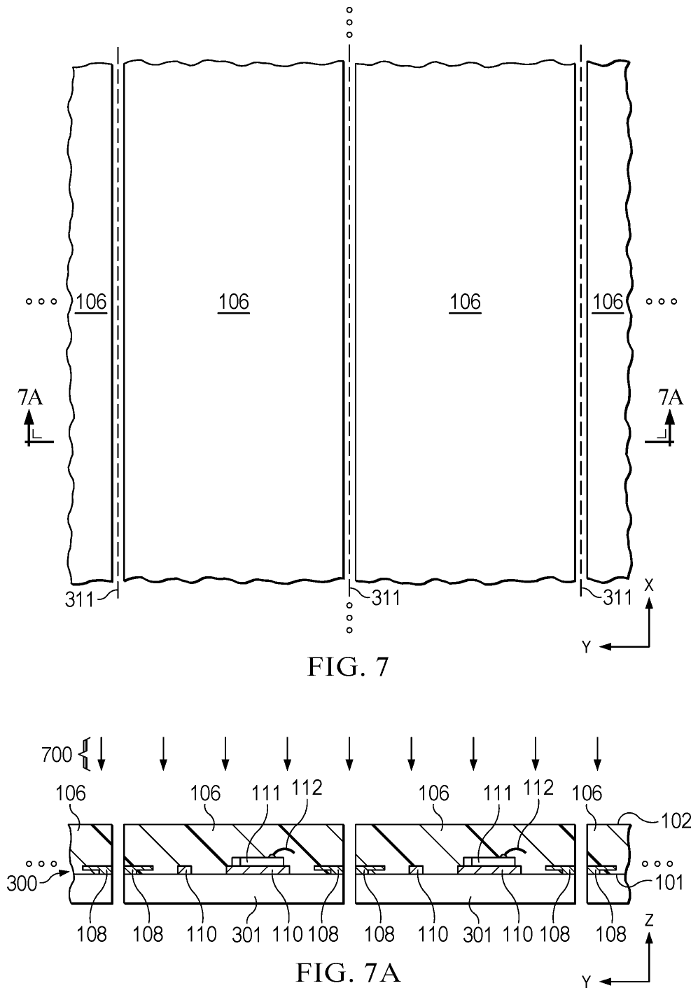

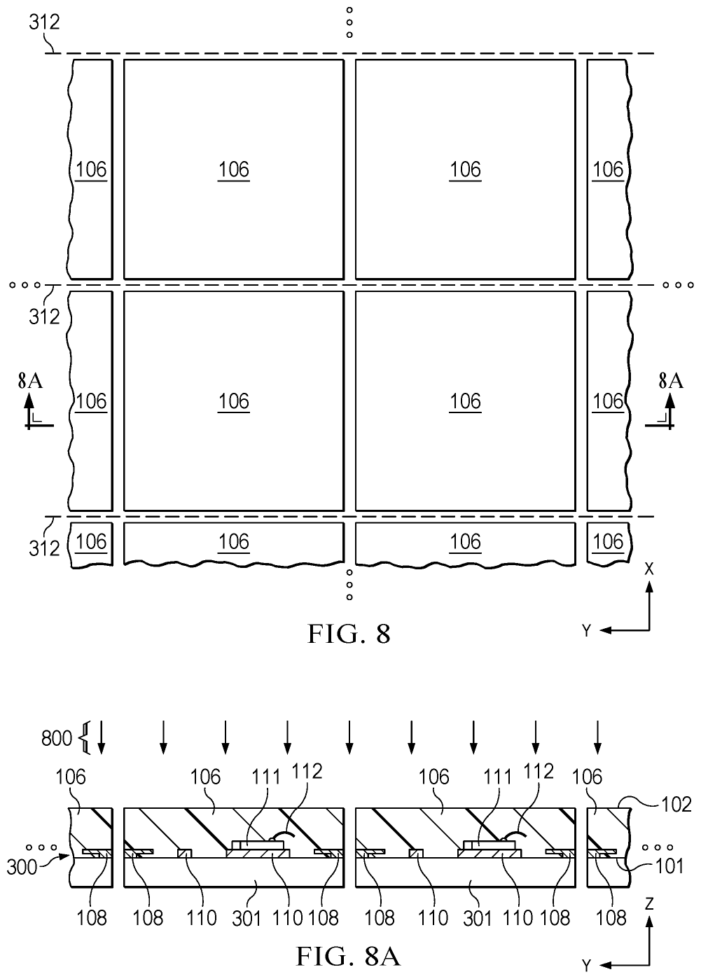

The method 200 also includes package separation at 208, 210, and 212, using any suitable cutting tools and techniques, such as saw cutting, laser cutting, etching, or combinations thereof. The cutting steps at 208, 210, and 212 can be performed in any suitable order. In one example, the cutting operations are automated, for example, using a programmable cutting tool with programmable patterns in order to implement cutting operations along the prospective cut lines 311, 312, and 313 illustrated in FIG. 3 above. The illustrated example includes a first package separation cut at 208 along the first direction X. FIGS. 7 and 7A show one example, in which a first cutting process 700 is performed that cuts through the package structure 106 and the metal bars 302 of the lead frame 300 along the first cut lines 311 that are parallel to the first direction X. At 210 in FIG. 2, the method 200 continues with a second package separation cut along the second direction Y. FIGS. 8 and 8A show one example, in which a second cutting process 800 is performed that cuts through the package structure 106 and further metal bars 302 of the lead frame 300 along the second cut lines 312 that are parallel to the second direction Y.

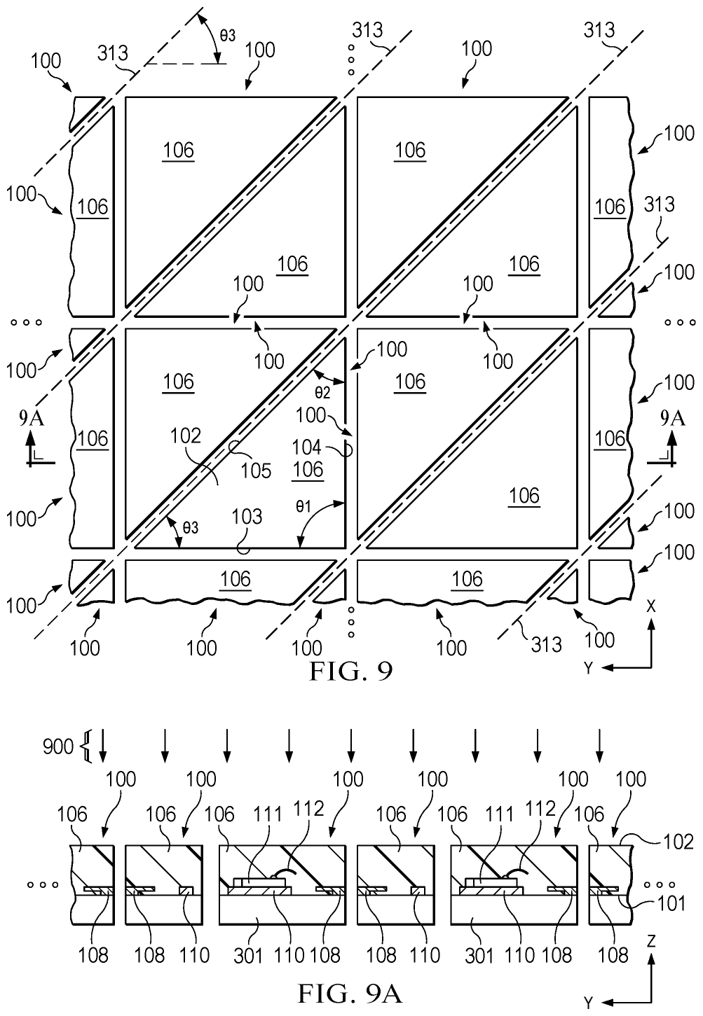

The method 200 also includes third package separation cutting at 212 along a third direction that is angled with respect to the first and second directions X and Y. FIGS. 9 and 9A show one example, in which a third cutting process 900 is performed that cuts through the package structure 106 and the first tie bars 109 along the third cut lines 313 that intersect opposite corners of the respective unit regions 304 and that bisect the respective unit regions 304 between the first and second metal die attach pads 110. In the illustrated example, the third cutting process 900 separates individual packaged electronic devices 100 from one another and from the starting panel structure. As seen in FIG. 9, moreover, the method 200 creates a pair of packaged electronic devices 100 in each of the respective rectangular unit regions. This advantageously doubles the number of electronic devices 100 that are concurrently fabricated in a panel compared with rectangular QFN or other rectangular SON package forms. In the example of FIG. 9, the third cut lines 313 are at a first angle of approximately 45° from the first direction X, and the third cut lines 313 are at a second angle of approximately 45° from the second direction Y. Other implementations can include one or more further package separation cutting operations, including a fourth package separation cut at 214 in FIG. 2 along a fourth direction that separates individual packaged electronic devices from one another and from a starting panel structure (not shown), for example, to create other forms of triangle shaped packaged electronic devices as illustrated and described further below in connection with FIG. 12.

FIGS. 10 and 10A illustrated example host system 1000 including a printed circuit board (PCB) 1002 and the packaged electronic device 100 of FIGS. 1-1E soldered to the PCB 1002. The reduced size of the packaged electronic device 100 facilitates increased component density on the PCB 1002 in combination with other devices or components (not shown). The described examples thus facilitate increased circuit density and/or reduced circuit size as well as reduced manufacturing process time and cost compared with QFN or other similar packaging types and forms.

FIG. 11 shows another example pair of triangular shaped packaged electronic devices during fabrication processing prior to package separation cutting operations in a panel or array 1100 with multiple columns and rows of respective unit regions 1104, one of which is illustrated. This example is fabricated using a starting lead frame panel or array having metal bars 1102 that extend along respective first and second directions X and Y, where the metal bars 1102 define the illustrated elongated rectangular unit region 1104, with respective conductive leads 1108 connected to the metal bars 1102 along the four sides of the unit region 1104. The illustrated unit region 1104 has two die attach pads 1110 with corresponding semiconductor dies 1111 mounted thereon. The die attach pads 1110 have elongated rectangular shapes with long sides that are parallel to a prospective third cut line 1123 that intersects opposite corners of the elongated rectangular unit region 1104 at non-zero angles with respect to the first and second directions X and Y. Bond wires 1112 electrically couple conductive pads of the semiconductor dies 1111 to respective ones of the leads 1108. This example also includes first tie bars 1109 that extend between the first and second die attach pads 1110 at non-zero angles to the first and second directions X and Y, as well as second tie bars 1107 that extend from corners of the respective die attach pads 1110 to respective ones of the metal bars 1102. FIG. 11 also shows prospective first cut lines 1121 that are parallel to the first direction X, prospective second cut lines 1122 that are parallel to the second direction Y, and the prospective third cut line 1123 that is angled with respect to the first and second directions X and Y. Subsequent processing (not shown) includes cutting along the first cut lines 1121, the second cut lines 1122, and the third cut lines 1123 in any suitable order to separate individual packaged electronic devices from one another and from the starting array structure. This provides a pair of packaged electronic devices for each of the respective rectangular unit regions 1104 of the array, where the finished packaged electronic device on the lower right in FIG. 11 has a triangular shape in the illustrated top view with a third side 1113, a fourth side 1114, and a fifth side 1105 in addition to top and bottom sides (not numerically designated). In this example, the planes of the third and fourth sides 1113 and 1114 intersect at a first angle θ1 that is approximately 90°, planes of the fourth and fifth sides 1114 and 1115 intersect at a second angle θ2, and planes of the third and fifth sides 1113 and 1115 intersect at a third angle θ3 that is greater than the second angle θ3 and less than the first angle θ1 due to the non-unity aspect ratio of the elongated rectangular unit regions 1104.

In other implementations using square or elongated rectangular unit regions (e.g., similar to those of FIGS. 1 and 11), different lead frame designs can be used in which the die attach pads are rectangular or other shapes, including rectangular die attach pads with sides that are parallel to the first and second directions X and Y. In these or other implementations, combinations of tie bars can be used that are aligned with one of the respective first and second directions X and Y and/or extend at non-zero angles with respect to the first and second directions X and Y.

FIG. 12 shows a top view of another example electronic device during fabrication prior to package separation cutting operations in a panel array of multiple square unit regions 1204 arranged in multiple columns and rows, one of which is illustrated. This example is fabricated using a starting lead frame panel or array having metal bars 1202 that extend along respective first and second directions X and Y. The metal bars 1202 define the illustrated square unit region 1204, with respective conductive leads 1208 connected to the metal bars 1202 along the four sides of the unit region 1204. The illustrated unit region 1204 has four die attach pads 1210 with corresponding semiconductor dies 1211 mounted thereon. The die attach pads 1210 have elongated rectangular shapes with sides that are parallel to a respective one of the first and second directions X and Y. Bond wires 1212 electrically couple conductive pads of the semiconductor dies 1211 to respective ones of the leads 1208. This example also includes first tie bars 1209 that extend between respective pairs of the die attach pads 1210 at non-zero angles to the first and second directions X and Y, as well as second tie bars 1207 that extend from the respective die attach pads 1210 to respective ones of the metal bars 1202. FIG. 12 also shows prospective first cut lines 1221 that are parallel to the first direction X, prospective second cut lines 1222 that are parallel to the second direction Y, a prospective third cut line 1223 that is angled with respect to the first and second directions X and Y, and a prospective fourth cut line 1224 that is angled with respect to the first and second directions X and Y.

In this example, subsequent package separation cutting (not shown) includes cutting along the first cut lines 1221, the second cut lines 1222, the third cut lines 1223, and the fourth cut line 1224 in any suitable order to separate individual packaged electronic devices from one another and from the starting array structure. This provides four packaged electronic devices for each of the respective rectangular unit regions 1204 of the array, where the finished packaged electronic device on the lower quadrant in FIG. 12 has a triangular shape in the illustrated top view with a third side 1213, a fourth side 1214, and a fifth side 1205 in addition to top and bottom sides (not numerically designated). In this example, the planes of the third and fourth sides 1213 and 1214 intersect at a first angle θ1 that is approximately 45°, planes of the fourth and fifth sides 1214 and 1215 intersect at a second angle θ2 that is approximately 90°, and planes of the third and fifth sides 1213 and 1215 intersect at a third angle θ3 that also approximately 45° due to the square shape of the unit regions 1204 and the use of the third and fourth cut lines 1223 and 1224 that individually intersect opposite corners of the unit regions 1204.

Described solutions and variants thereof advantageously facilitates increased numbers of packaged electronic devices per panel or strip and achieve increased panel utilization to significantly reduce manufacturing cost with a slight trade off in increased number of device separation cutting steps, and also provide reduced packaged electronic device size advantages compared to conventional rectangular or square QFN and SON designs. This helps achieve increased circuit density in applications requiring aggressively minimized spaces in addition to reducing manufacturing cost by increasing the number of units within a panel or strip while maintaining strip sizes. In further possible examples, laser cutting, or other programmable automated cutting equipment and programming may be used to implement different forms and shapes of finished packaged electronic devices, for example, using nonlinear, curvilinear, and/or piecewise linear cut lines or combinations thereof.

Modifications are possible in the described examples, and other implementations are possible, within the scope of the claims.

What is claimed is:

1. An electronic device, comprising:
a package structure having a first side, a second side, a third side, a fourth side, and a fifth side, the first side extending in a first plane of orthogonal first and second directions, the second side extending in a second plane of the first and second directions, the second side spaced apart from the first side along a third direction that is orthogonal to the first and second directions, the third side extending along the third direction from the first side to the second side, the third side extending along the second direction from the fourth side to the fifth side, the fourth side extending along the third direction from the first side to the second side, the fourth side extending along the first direction from the third side to the fifth side, and the fifth side extending from the third side to the fourth side;
a semiconductor die; and
a set of conductive leads along the third side, one of the set of conductive leads electrically coupled to a conductive terminal of the semiconductor die;
wherein the package structure encloses a portion of the semiconductor die and portions of the set of conductive leads, and the package structure exposes further portions of the set of conductive leads along the first side, and additional portions of the set of conductive leads along the third side.

2. The electronic device of claim 1, wherein a third plane of the third side and a fourth plane of the fourth side are at a first angle, a fifth plane of the fifth side and the fourth plane are at a second angle, the third and fifth planes are at a third angle, and the first angle is greater than the second and third angles.

3. The electronic device of claim 2, wherein the first angle is approximately 90°, the second angle is approximately 45°, and the third angle is approximately 45°.

4. The electronic device of claim 2, wherein the second and third angles are equal.

5. The electronic device of claim 1, further comprising a die attach pad and a tie bar, wherein:
the semiconductor die is mounted on the die attach pad;
the tie bar is connected to the die attach pad; and
a portion of the tie bar is exposed along one of the third, fourth, and fifth sides of the package structure.

6. The electronic device of claim 5, wherein the tie bar is exposed along the fifth side of the package structure.

7. The electronic device of claim 6, further comprising a second tie bar, the second tie bar exposed along one of the third and fourth sides of the package structure.

8. The electronic device of claim 6, wherein the tie bar is exposed along one of the third and fourth sides of the package structure.

9. The electronic device of claim 5, wherein the tie bar is spaced apart from the first side of the package structure along the third direction.

10. The electronic device of claim 5, wherein the die attach pad has a rectangular shape with opposite sides parallel to the fifth side of the package structure.

11. The electronic device of claim 1, further comprising a second set of conductive leads along the fourth side, one of the second set of conductive leads electrically coupled to a second conductive terminal of the semiconductor die, wherein the package structure encloses portions of the second set of conductive leads, and the package structure exposes further portions of the second set of conductive leads along the first side and additional portions of the second set of conductive leads along the fourth side.

12. A lead frame panel, comprising an array of rectangular unit regions arranged in rows along a first direction and columns along an orthogonal second direction, adjacent unit regions joined by metal bars that extend along the respective first and second directions on four sides of the respective rectangular unit regions, the respective unit regions including:
first and second metal die attach pads in a plane of the first and second directions;
a first set of conductive leads connected to a first one of the metal bars along a first side of the rectangular unit region;
a second set of conductive leads connected to a second one of the metal bars along a second side of the rectangular unit region;
a third set of conductive leads connected to a third one of the metal bars along a third side of the rectangular unit region;
a fourth set of conductive leads connected to a fourth one of the metal bars along a fourth side of the rectangular unit region; and
a tie bar connected to and extending between the first and second metal die attach pads, the tie bar intersecting a prospective cut line that bisects the respective unit region and that intersects opposite corners of the respective unit region.

13. The lead frame of claim 12, wherein the first and second die attach pads have rectangular shapes with opposite sides parallel to the prospective cut line.

14. The lead frame of claim 12, wherein the respective unit regions further include a set of second tie bars, the respective second tie bars extending from one of the metal die attach pads to a respective one of the metal bars.

15. The lead frame of claim 12, wherein the respective unit regions are square.

16. A method of fabricating an electronic device, the method comprising:
attaching first and second semiconductor dies to respective first and second die attach pads in each of an array of rectangular unit regions arranged in rows along a first direction and columns along an orthogonal second direction of a lead frame;
for each respective unit region, electrically coupling a conductive terminal of the first semiconductor die to one of a first set of conductive leads of the respective unit region, and electrically coupling a conductive terminal of the second semiconductor die to one of a second set of conductive leads of the respective unit region;
performing a molding process that forms a package structure that encloses the first and second semiconductor dies and portions of the first and second sets of conductive leads;
performing a first cutting process that cuts through the package structure and metal bars of the lead frame along first cut lines that are parallel to the first direction;
performing a second cutting process that cuts through the package structure and further metal bars of the lead frame along second cut lines that are parallel to the second direction; and
performing a third cutting process that cuts through the package structure and tie bars along third cut lines that intersect opposite corners of the respective unit regions and bisect the respective unit regions between the first and second metal die attach pads.

17. The method of claim 16, wherein the third cutting process separates individual packaged electronic devices from one another and from a starting panel structure.

18. The method of claim 17, wherein the third cut lines are at a first angle of approximately from the first direction, and the third cut lines are at a second angle of approximately 45° from the second direction.

19. The method of claim 16, wherein the third cut lines are at a first angle of approximately from the first direction, and the third cut lines are at a second angle of approximately 45° from the second direction.

20. The method of claim 16, further comprising:
performing a fourth cutting process that cuts through the package structure along fourth cut lines that are orthogonal to the third cut lines, wherein the fourth cutting process separates individual packaged electronic devices from one another and from a starting panel structure.
